(19) United States
(12) Patent Application Publication
(10) Pub. No.: US 2008/0166870 A1
(43) Pub. Date: Jul. 10, 2008

(54) Fabrication of Interconnect Structures

(75) Inventors: Elbert Emin Huang, Carmel, NY (US); Hyungjun Kim, Lagrangeville, NY (US); Robert Dennis Miller, San Jose, CA (US); Satyanarayana Venkata Nitta, Poughquag, NY (US); Sampath Purushothaman, Yorktown Heights, NY (US)

Correspondence Address: CONNOLLY BOVE LODGE & HUTZ LLP;(FOR IBM YORKTOWN), P.O. BOX 2207, WILMINGTON, DE, 19899-2207, US

(73) Assignee: International Business Machines Corporation, Armonk, NY (US)

(21) Appl. No.: 11/570,014

(22) PCT Filed: May 23, 2005
(86) PCT No.: PCT/US05/18196

§ 371 Date: Nov. 21, 2007

Related U.S. Application Data
(60) Provisional application No. 60/576,924, filed on Jun. 4, 2004.

(51) Int. Cl. H01L 21/768

(52) U.S. Cl. 438/619; 438/623; 257/E21.576

(57) ABSTRACT

Interconnect structures are fabricated by methods that comprise depositing a thin conformal passivation dielectric and/or diffusion barrier cap and/or hard mask by an atomic layer deposition or supercritical fluid based process.

### CROSS-REFERENCE TO RELATED APPLICATIONS

This application claims priority under 35 USC 119(e) from U.S. Provisional patent application Ser. No. 60/576,924 filed Jun. 4, 2004 entitled “Fabrication of Interconnect Structures Incorporating Dielectrics Coated by Plasma Free Deposition Methods, entire disclosure of which is incorporated herein by reference.

### TECHNICAL FIELD

The present disclosure relates to forming an interconnect structure. In particular, the present disclosure relates to a process that comprises depositing a thin conformal passivation dielectric and/or diffusion barrier cap and/or hard mask. The present disclosure is especially concerned with fabricating damascene and dual damascene structures.

### BACKGROUND OF THE INVENTION

Performance of high end microprocessor chips is increasingly limited by the signal propagation delay in the interconnection wiring used to enable the connection between the various devices on such chips. Commonly referred to as the back end of the line (BEOL) interconnects, delays in these wires are determined by the product of the resistance, R, and the capacitance, C, associated with them. While R has been reduced through the use of Cu instead of Al in the BEOL wiring, the reduction of C is achieved through the reduction of the dielectric constant, k, of the insulating medium that surrounds the interconnect wires. Changing the intermetal dielectric (IMD) from silicon dioxide (k˜4) to lower k IMD's such as fluorinated silica (k˜3.6) and organosilicates made by CVD or spin on coatings (k˜2.7-3.2) has been employed to further reduce BEOL capacitance. Additional reduction in k requires the introduction of porous ultra-low k (ULK, k<2.5) IMDs and ultimately the use of airgaps as an IMD to achieve the lowest possible capacitance levels. These ultra-low k structures are quite fragile and require additional processing or specialized processes to enable their fabrication.

One prior art method of creating interconnect wiring networks on such a small scale is the dual damascene (DD) process. In the standard DD process, an inter-metal dielectric (IMD), is coated on the substrate. The inter-metal dielectric includes a via level dielectric and a line level dielectric. These two inter-metal dielectric layers can be made of the same or different insulating films and in the former case applied as a single monolithic layer. A hard mask layer or a layered stack is optionally employed to facilitate etch selectivity and to serve as a polish stop. The wiring interconnect network includes two types of features: line features that traverse a distance across the chip, and the via features which connect lines together in different levels of interconnects in a multilevel stack. Historically, both layers are made from an inorganic glass such as silicon dioxide (SiO₂) or a fluorinated silica glass (FSG) film deposited by plasma enhanced chemical vapor deposition (PECVD).

In the dual damascene process, the position of the lines and the vias are defined lithographically in separate photoresist layers respectively, and transferred into the hard mask and IMD layers using reactive ion etching processes. Such an exemplary process sequence is called a “line-first” approach. After the trench formation, lithography is used to define a via pattern in a photoresist layer and the pattern is transferred into the dielectric material to generate a via opening. This recessed structure is then coated with a conducting liner material or material stack that serves to protect the conductor metal lines and vias and serves as an adhesion layer between the conductor and the IMD. This recess is then filled with a conducting fill material over the surface of the patterned substrate.

The fill is most commonly accomplished by electroplating of copper although other methods such as chemical vapor deposition (CVD) and other materials such as Al or Au can also be used. The fill and liner materials are then chemical-mechanical polished (CMP) to be coplanar with the surface of the hard mask. A capping material is deposited as a blanket film to passivate the exposed metal surface and to serve as a diffusion barrier between the metal and any additional IMD layers to be deposited over them. Silicon nitride, silicon carbide, and silicon carbonitride films deposited by PECVD are typically used as the capping material. This process sequence is repeated for each level of the interconnects on the device. Since two interconnect features are simultaneously defined to form a conductor in-laid within an insulator by a single polish step, this process is designated a dual damascene process.

Although a line first approach was described above, other sequences where vias are formed before the trench is patterned are also possible. The major issues and the solutions provided by the inventive approach detailed below in the present application are, however, common to all such variants of the dual damascene process.

Conventional dual damascene integration of the ULK IMD materials has been shown to have several problems. The sensitivity of the porous IMDs to plasma exposures required to strip photoresist and RIE residues results in an increase in water uptake and dielectric constant of these films. Low mechanical strength and adhesion leads to sporadic delamination of the IMD at its interfaces with the polish stop layer and diffusion barrier cap layer. Other issues stemming from their mechanical fragility include damage during dicing of the wafers to form chips and during wire bonding to bond pads on the chips.

Several methods to avoid the use of porous ULK IMDs have been proposed. The first method is the formation of closed air gaps by etching back the IMD between the lines and pinching off the top of the gaps by depositing a poor gap filling plasma deposited dielectric, as demonstrated by Arnal et al (IITC, 2001). However, this integration scheme cannot be easily extended to future generations of fine ground rule interconnects due to the inability to provide sub-minimum ground rule lithography required before the etch back step. This lithography is designed to protect the dielectric diffusion barrier on top of the Cu during etch back. The absence of this lithography step leaves the Cu surface open during etch back causing Cu sputtering. Additionally, protecting the copper lines after etch back using conventional CVD leads to the lining of the post etch back trenches with a thick layer of dielectric leaving very little space left for the air gap formation. It is also very difficult to use conventional spin-on depositions to get films which are thin and conformal since spin-on deposition solutions with low solids content have a tendency to puddle or accumulate excessively at the bottom of the trench.

A second alternative to dual damascene integration of ULK films is the etch back and gap fill integration (EBGF) (e.g. U.S. Pat. No. 6,346,484, U.S. Pat. No. 6,551,924, and U.S. Pat. No. 6,413,854). In this method, after the etch back of the IMD from between the lines, a porous ULK is used to fill the gaps. The gap fill dielectric (GFD) is then planarized by CMP and a diffusion barrier cap is deposited after a plasma cleaning step. In this scheme, the lack of a polish stop layer during the GFD planarization polish, leads to GFD dishing. Additionally, during the barrier (cap) deposition, the porous ILD is exposed to process plasmas that are used to clean up the Cu surface, thus damaging it and making it prone to electrical leakage and breakdown. Lastly, the requirements of good gap-filling and planarization limit the choice of GFD to low molecular weight precursor solutions often resulting in a trade off in other desirable attributes such as mechanical strength.

Conventional CVD deposited barriers, as mentioned above suffer from excessive thickness and therefore occupy too much space in the post etch back structure thus resulting in a very high effective k of this structure. It would therefore be desirable to be able to provide these conformal coatings to line the side walls and bottoms of inter-metal trenches in etched back structures. Methods to form hard mask and diffusion barrier cap films without introducing plasma damage to the ULK films would also be advantageous for conventional damascene and dual damascene as well as the EBGF integration schemes. Moreover, it would be seen desirable to provide a method of depositing gap fill material that alleviates the low molecular weight restrictions.

### SUMMARY

The present disclosure discloses methods that address these needs and describes structures that are enabled by the use of the methods. One aspect of the present disclosure relates to a method forming an air gap structure. In particular, the method comprises

a) forming a dual damascene interconnect structure with at least two interconnect lines and at least one via connected to at least one of the least two interconnect lines, and wherein the at least two interconnect lines and the at least one via are embedded in a first dielectric;

b) removing the first dielectric from between the at least two interconnect lines to a depth of at least equal to the height of the lines, at least two interconnect lines;

conformally depositing a thin passivation dielectric by supercritical fluid based process to coat the tops and exposed sidewalls of the lines and the bottom of the via between the at least two interconnect lines;

and depositing a non conformal second dielectric film by a process for pinching off the gap between the at least two interconnect lines at the top forming a closed air gap structure.

Another aspect of the present disclosure relates to a method of an interconnect structure which comprises:

forming a dual damascene interconnect structure with at least two interconnect lines and at least one via connected to at least one of the at least two interconnect lines embedded in a first dielectric;

removing the first dielectric from between the at least two interconnect lines to a depth of at least equal to the height of the lines;
depositing a thin formal passivation dielectric by a supercritical fluid based process or an atomic layer deposition from a tertiary amine based reagent and/or silylating agent to coat the tops and exposed sidewalls of said lines and the bottom of the via between the at least two interconnect lines;

filling the space (via and line) between the at least two interconnect lines with a second dielectric with a lower dielectric constant than the first dielectric;

planarizing the second dielectric by polishing using the conformal dielectric as polish stop layer;

and optionally capping the top surface of the resulting structure with a third dielectric.

A further aspect of the present disclosure relates to a fabricating a damascene or dual damascene interconnect structure which comprises forming a damascene or dual damascene interconnect structure with at least one interconnect line embedded in a first dielectric; and capping the top of the at least one interconnect line with a barrier cap dielectric deposited by a process selected from the group consisting of a supercritical fluid based process and an atomic layer deposition from a tertiary amine based reagent and/or silylating agent.

Another aspect of the present disclosure relates to fabricating a damascene or dual damascene interconnect structure which comprises forming a damascene or dual damascene interconnect structure with at least two interconnect lines and wherein the at least two interconnect lines are embedded in a first dielectric; and depositing a dielectric hard mask spanning the space between said interconnect lines and nominally coplanar with the top surface of said lines, and the optional hard mask by a process selected from the group consisting of a supercritical fluid based process and an atomic layer deposition from a tertiary amine-based reagent and/or silylating agent.

A still further aspect of the present disclosure relates to fabricating a damascene or dual damascene interconnect structure which comprises a damascene or dual damascene interconnect structure with at least two interconnect lines and wherein the at least two interconnect lines and the at least one via are embedded in a first dielectric; and optionally a dielectric hard mask spanning the space between said interconnect lines and nominally coplanar with the top surface of said lines and a diffusion barrier cap dielectric on top of the at least two interconnect lines; which comprises
depositing the first dielectric and optionally the dielectric hard mask using supercritical fluid based processing;

patterning photoresist layers to form the at least two interconnect line patterns;

transferring the at least two interconnect line patterns into the dielectric using photolithography and reactive ion etching;

stripping the residual photoresist using plasma ashing;

repairing any plasma damage to the first dielectric and the optional hard mask using a supercritical fluid based silylation treatment;

filling the interconnect lines with a conductive liner and a conductive fill material;

planarizing the conductive liner and conductive fill material using chemical mechanical polishing;

cleaning the top of said at least two interconnect lines and said optional dielectric hard mask using supercritical fluid based cleaning solutions;

and depositing a diffusion barrier cap dielectric using a process selected from the group consisting of a supercritical fluid based process and an atomic layer deposition from a tertiary amine based reagent and/or silylating agent.

The present disclosure also relates to structures obtained by any of the above processes.

Other and further objects, advantages and features of the present disclosure will be understood by reference to the following specification in conjunction with the annexed drawings, wherein like parts have been given like numbers.

### BRIEF DESCRIPTION OF THE DRAWINGS

FIGS. 1a, 1b, 1c, 1d, 1e, 1f and 1g illustrate cross-sectional views at various stages of a process according to the present disclosure.

### BEST AND VARIOUS MODES

The present disclosure relates to forming interconnect structures. The method of the present disclosure comprises employing a non plasma process and particularly supercritical fluid based process and preferably supercritical carbon dioxide (SC CO₂) based evaporative mass transport by depressurization for the formation of various dielectric films mentioned above leading to integrated BEOL structures to alleviate problems discussed above of the prior art. While SC CO₂ is preferred as the carrier medium, SC fluids of propane, butane, butene, water and the like can also be used without deviating from the spirit of the present disclosure. SC CO₂ is advantageous due to cost and environmental reasons. The supercritical fluid deposition process may be used to deposit thin films of higher molecular weight materials such as oligomers and polymers.

The supercritical fluid deposition process enables the deposition of conformal films which would otherwise be non-conformal with spin-coating. The supercritical fluid deposition process such as the SC CO₂ technique provides the additional advantage of liquid-like densities with very low surface tensions which could be very important for coating very small features.

A further advantage of the use of supercritical fluids for the EBGF integration pertains to the gap fill ILD material and its deposition. Currently, the gap fill properties of the spin on ILD materials are controlled by the molecular weight of the precursor material used and the carrier solvent properties such as surface tension and viscosity. These in turn dictate that low molecular weight (typically less than about 10,000 Daltons) precursors be used and dissolved in a limited set of solvents that constrains the available choices. Often, a tradeoff between good gap fill characteristics and robust electrical and mechanical properties have to be made leading to less robust final structures. The unique aspects of the supercritical fluids such as SC CO₂ with respect to near zero surface tension and gas like viscosities and their ability to dissolve the ILD precursors utilizing small amounts of added co-solvents can enable the gap filling using precursors with larger and a wider range of molecular weights. Thus it is possible to independently engineer and select the gap fill ILD precursor based more on the final film properties (electrical and mechanical) without being constrained by the restrictions of conventional gap fill deposition processes such as spin coating.

With respect to the DD integration scheme, SC CO₂ based processing enables the formation of the hard mask and diffusion barrier cap layers on the ULK ILD using appropriate precursor materials dissolved in SC CO₂ with optional co-solvents. These are exemplified by but not limited to organosilicates, polysilanes, polyoxycarbosilanes, polysilazanes, polyoxycarbosilazanes, polycarbosilanes, polysilasilazanes, polysilacarbosilanes, polysiloxazanes, polycarbosilazanes, polysilylcarbodiimides, polysilacarbosilazanes, polyalkenylsilanes, polyalkylsilanes, polyalkynylsilanes, polyarylsilanes, polysilsesquiazanes dissolved in SC CO₂ with suitable co-solvents such as alcohols, ethers (linear or cyclic), gamma-butryolactone, cyclic carbonates, esters, NMP, PGMEA, hexane, substituted aromatics and ketones (acyclic and cyclic).

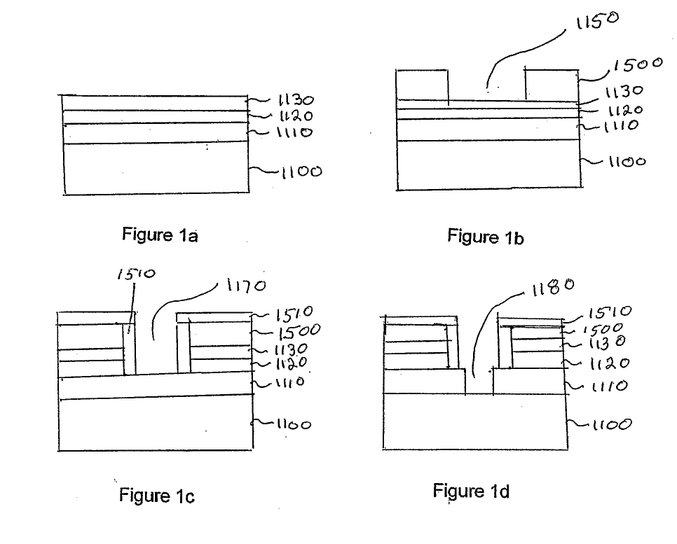

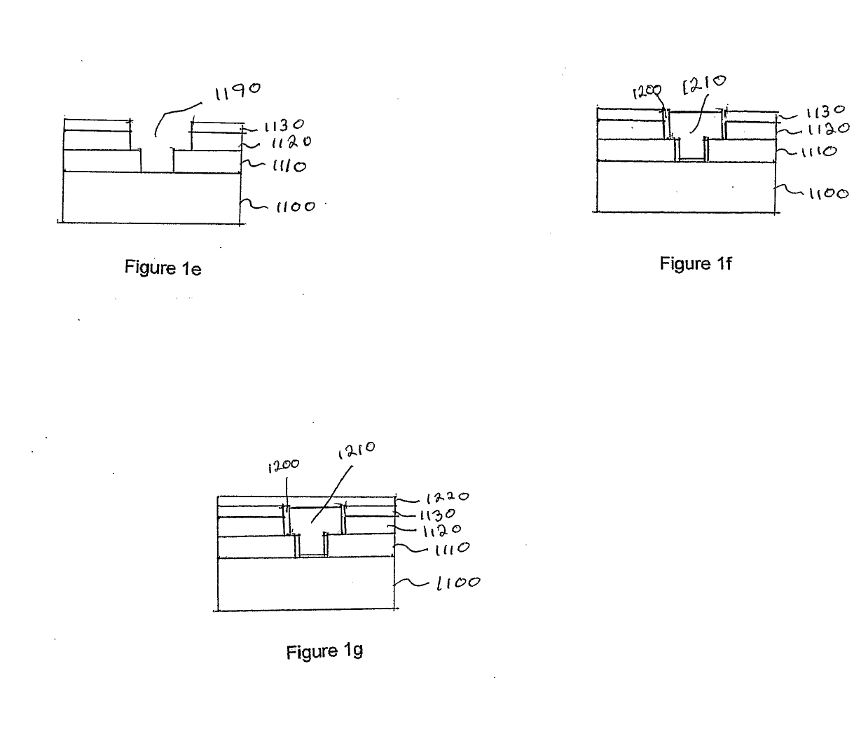

Additionally, suitable co-solvents can also be used to clean the surface of preexisting copper interconnects after chemical-mechanical polishing (CMP) of the DD structure (see FIG. 1f) so that diffusion barrier caps such as polycarbosilanes, polyoxycarbosilanes, polycarbosilazanes, polyoxycarbosilazanes or polysilazanes can then be formed on top without the need for potentially damaging plasma treatments or plasma mediated deposition as practiced in the currently known prior art. Plasma exposure of many of the underlying dielectrics, in particular, the low k and ultra low k ILDs can potentially degrade the electrical breakdown and leakage current of the hard mask and ILD films.

Additionally, it is possible to use suitable SC CO₂ based silylation with mono or multi functional silylating agents to modify the surface of the hard mask or the ILD from the state resulting after the CMP step so that the interface between the diffusion barrier cap and this modified region is more robust from an adhesion as well as an electrical leakage point of view. The combined process comprising the cleaning of the Cu line surface, surface treatment of the hard mask, followed by the coating of the diffusion barrier cap layer all of which are done using SC CO₂-based processes is a unique way to achieve a structure that would result in integrated structures with improved dielectric breakdown and electromigration properties due to much reduced plasma exposures. SC CO₂ based silylation can also be used to repair damaged ultra low k ILD's after reactive ion etch and resist strips involved in patterning as described in Application 60/499,856 filed by some of the present inventors, the entire disclosure of which is incorporated herein by reference. Examples of silylating agent include alkoxysilanes, aminosilanes, chlorosilanes, silazanes and mixtures thereof.

The present disclosure also relates to using atomic layer deposition (such as plasma enhanced ALD) of certain types of materials for depositing ultra thin conformal cap dielectric layers of silicon nitride. ALD according to the present disclosure employs a tertiary amine based reagent gas such as trimethyl amine and/or a silylating agent such as tert butoxysilanols; or an amino-silane precursor such as bis-dimethylaminodimethylsilane, tris dimethylaminomethyl silane or other multi-functional silylating agents, including those with bridging substituents between the reactive functionality. Other polyfunctional silanes that would be useful for this purpose include trichloro, triacetoxy including vinyl substituted silane materials for post deposition crosslinking, hexachlorodisiloxane and the like. Bridging substituents may include vinyl, ethynyl, substituted ethynyl, aryl groups which also may undergo additional crosslinking upon heating, treatment with UV radiation, ionizing radiation and the like. These layers can also be formed through the use of SC CO₂ with suitable co-solvents if needed to deposit materials such as polysilazanes and polycarbosilanes.

Both ALD and SC CO₂ based deposition enable the deposition of conformal films which would otherwise be non-conformal with spin-coating. The SC CO₂ technique provides the additional advantage of liquid-like densities with very low surface tensions which could be very important for coating very small features. ALD being a gas phase process also offers this advantage. For example, polycarbosilanes deposited by spin coating from a solution can accumulate at the bottom of the etch back structure, thus increasing the effective dielectric constant. Furthermore, it is unclear how thin a film can be deposited. In the present disclosure, films in the range of 5 to 10 nm can be deposited which is highly desirable. Furthermore, the structure that results from the deposition of the ultra thin conformal barrier after etchback is unique and solves the major issues for the pinch-off based air gap creation as well as for the EBGF integration that are mentioned above. First, for the EBGF scheme, the conformal coating acts as a CMP stop layer during the polish back of the GFD so that the Cu lines can be protected. In the air gap scheme, the need for sub-ground rule lithography is eliminated and the thin conformal dielectric is used as a cap that covers both the sidewalls and the top surfaces of the interconnect lines after the full etch back step to provide the diffusion barrier function.

To further facilitate an understanding of the present disclosure, reference will be made to the figures showing a dual damascene process. In a dual damascene process according to the present disclosure, an inter-metal dielectric (IMD), shown as two layers 1110, 1120 is coated on the substrate 1100, FIG. 1a. The via level dielectric is 1110 and the line level dielectric is 1120. A hard mask layer or a layered stack 1130 is optionally employed to facilitate etch selectivity and to serve as a polish stop. If desired, the hard mask layer can be deposited by methods according to this disclosure as discussed above.

The wiring interconnect network contains two types of features: line features that traverse a distance across the chip, and the via features which connect lines in different levels of interconnects in a multilevel stack together. Historically, both layers are made from an inorganic glass like silicon dioxide (SiO₂) or a fluorinated silica glass (FSG) film deposited by plasma enhanced chemical vapor deposition (PECVD). According to the present disclosure the line level dielectric 1120 can be deposited by the methods according to this disclosure as discussed above.

In the dual damascene process, the position of the lines 1150 and the vias 1170 are defined lithographically in photoresist layers 1500 and 1510 respectively, FIGS. 1b and 1c, and transferred into the hard mask and IMD layers using reactive ion etching processes. The process sequence shown in FIG. 1 is called a “line-first” approach. After the trench formation, lithography is used to define a via pattern 1170 in the photoresist layer 1510 and the pattern is transferred into the dielectric material to generate a via opening 1180, FIG. 1d. The dual damascene trench and via structure 1190 is shown in FIG. 1e after the photoresist has been stripped. This recessed structure 1190 is then coated with a conducting liner material or material stack 1200 that serves to protect the conductor metal lines and vias and serve as an adhesion layer between the conductor and the IMD. This recess is then filled with a conducting fill material 1210 over the surface of the patterned substrate. The fill is most commonly accomplished by electroplating of copper although other methods such as chemical vapor deposition (CVD) and other materials such as Al or Au can also be used. The fill and liner materials are then chemically-mechanically polished (CMP) to be coplanar with the surface of the hard mask and the structure at this stage is shown in FIG. 1f. A capping material 1220 is deposited as a blanket film, as is depicted in FIG. 1g to passivate the exposed metal surface and to serve as a diffusion barrier between the metal and any additional IMD layers to be deposited over them. The capping layer can be deposited by methods according to the present disclosure as discussed above.

This process sequence is repeated for each level of the interconnects on the device. Since two interconnect features are simultaneously defined to form a conductor in-laid within an insulator by a single polish step, this process is designated a dual damascene process. Although a line first approach was described above, other sequences where vias are formed before the trench is patterned are also possible. The major issues and the solutions provided by the inventive approach detailed below in the present application are, however, common to all such variants of the dual damascene process.

All publications and patent applications cited in this specification are herein incorporated by reference, and for any and all purposes, as if each individual publication or patent application were specifically and individually indicated to be incorporated by reference.

The foregoing description of the invention illustrates and describes the present invention. Additionally, the disclosure shows and describes only the preferred embodiments of the invention but, as mentioned above, it is to be understood that the invention is capable of use in various other combinations, modifications, and environments and is a capable of changes or modifications within the scope of the invention concept as expressed herein, commensurate with the above teachings and/or the skill or knowledge of the relevant art. The embodiments described hereinabove are further intended to explain best modes known of practicing the invention and to enable others skilled in the art to utilize the invention in such, or other embodiments and with the various modifications required by the particular applications or uses of the invention. Accordingly, the description is not intended to limit the invention to the form disclosed herein. Also, it is intended that the appended claims be construed to include alternative embodiments.

What is claimed is:

1. A method of forming an air gap interconnect structure which comprises:
a) forming a dual damascene interconnect structure with at least two interconnect lines and at least one via connected to at least one of the least two interconnect lines, and wherein the at least two interconnect lines and the at least one via are embedded in a first dielectric;
b) removing the first dielectric from between the at least two interconnect lines to a depth of at least equal to the height of the lines and forming a gap between the at least two interconnect lines;
conformally depositing a thin passivation dielectric by a supercritical fluid based process or an atomic layer deposition from a tertiary amine based reagent and/or silylating agent to coat the tops and exposed sidewalls of the lines and the bottom of the via between the at least two interconnect lines,
and depositing a non conformal second dielectric film by a process for pinching off the gap between the at least two interconnect lines at the top forming a closed air gap structure.

2. The method according to claim 1 wherein the first dielectric is selected from the group consisting of porous and nonporous versions of silicon oxide, fluorinated silicon oxide, organosilicates and, organic dielectric.

3. The method according to claim 2 wherein the organic dielectric is selected from the group consisting of polyimides, polyarylenes, polyarylene ethers, polyazoles, polyquinolines and quinoxalines, cyclic polyolefins, polyaryl cyanates and combinations thereof.

4. The method according to claim 1 which comprises removing the first dielectric by a process selected from the group consisting of wet chemical etching, reactive ion etching, photochemical etching and combinations thereof.

5. The method according to claim 1 wherein the conformal passivation dielectric is selected from the group consisting of amorphous films of silicon nitride, silicon carbide, silicon carbonitride, polycarbosilanes, polyoxycarbosilanes, polycarbosilazanes, polyoxycarbosilazanes or polysilazanes and combinations thereof.

6. The method according to claim 5 wherein the conformal passivation dielectric has a thickness of about 1 to 20 nm and is deposited by a supercritical carbon dioxide-based deposition with optional co-solvents.

7. The method according to claim 6 wherein the thickness of the conformal passivation dielectric is about 5 to 10 nanometers.

8. A method of an interconnect structure which comprises:
forming a dual damascene interconnect structure with at least two interconnect lines and at least one via connected to at least one of said at least two interconnect lines embedded in a first dielectric;
removing the first dielectric from between the at least two interconnect lines to a depth of at least equal to the height of the lines;
depositing a thin formal passivation dielectric by a supercritical fluid based process or an atomic layer deposition from a tertiary amine based reagent and/or silylating agent to coat the tops and exposed sidewalls of said lines and the bottom of the via between the at least two interconnect lines;
filling the space between the at least two interconnect lines with a second dielectric with a lower dielectric constant than the first dielectric;
planarizing the second dielectric by polishing using the conformal dielectric as polish stop layer;
and optionally capping the top surface of the resulting structure with a third dielectric.

9. The method according to claim 8 wherein the first dielectric is selected from the group consisting of porous and nonporous versions of silicon oxide, fluorinated silicon oxide, organosilicates and, organic dielectric.

10. The method according to claim 9 wherein the organic dielectric is selected from the group consisting of polyimides, polyarylenes, polyarylene ethers, polyazoles, polyquinolines and quinoxalines, cyclic polyolefins, polyaryl cyanates and combinations thereof.

11. The method according to claim 8 which comprises removing the first dielectric by a process selected from the group consisting of wet chemical etching, reactive ion etching, photochemical etching and combinations thereof.

12. The method according to claim 8 wherein the conformal passivation dielectric is selected from the group consisting of amorphous films of silicon nitride, silicon carbide, silicon carbonitride, polycarbosilanes, polyoxycarbosilanes, polycarbosilazanes, polyoxycarbosilazanes or polysilazanes and combinations thereof.

13. The method according to claim 8 wherein the conformal passivation dielectric has a thickness of about 1 to 20 nm.

14. The method according to claim 13 wherein the thickness of the conformal passivation dielectric is about 5 to 10 nanometers.

15. The method according to claim 13 wherein the optional co-solvent is selected from the group consisting of NMP, PGMEA, hexane, heptane, xylenes, alcohols, linear ethers, cyclic ethers, gamma-butryolactone, cyclic carbonates esters, substituted aromatics, acyclic ketones and cyclic ketones.

16. The method according to claim 8 wherein the second dielectric for filling the space between the at least two interconnect lines is selected from the group consisting of ultra low k porous versions of silicon oxide, fluorinated silicon oxide, organosilicates and organic dielectric.

17. The method according to claim 8 wherein the second dielectric is deposited using supercritical carbon dioxide-based processing with an optional co-solvent.

18. The method according to claim 17 wherein the optional co-solvent is selected from the group consisting of NMP, PGMEA, hexane, heptane, xylenes, alcohols, linear ethers, cyclic ethers, gamma-butryolactone, cyclic carbonates, esters, substituted aromatics, acyclic ketones and cyclic ketones.

19. The method according to claim 8 wherein the optional third dielectric is selected from the group consisting of amorphous films made up of the elements of silicon, carbon, oxygen and hydrogen, and optionally nitrogen in combination.

20. The method according to claim 19 wherein the third dielectric further comprises additional functionality which undergoes additional crosslinking upon heating, treatment with UV radiation, ionizing radiation or combinations thereof.

21. The method according to claim 8 wherein the optional third dielectric is deposited by a non-plasma deposition process.

22. A method for fabricating a damascene or dual damascene interconnect structure which comprises forming a damascene or dual damascene interconnect structure with at least two interconnect lines and wherein the at least two interconnect lines are embedded in a first dielectric; and capping the top of the at least two lines with a barrier cap dielectric deposited by a a supercritical fluid based process or an atomic layer deposition from a tertiary amine based reagent and/or silylating agent.

23. The method according to claim 22 wherein the barrier cap dielectric is selected from the group consisting of silanes, poly-oxycarbosilanes, poly-silazanes, poly-oxycarbosilazanes, polycarbosilanes, polysilasilazanes, polysilacarbosilanes, polysiloxazanes, polycarbosilazanes, polysilylcarbodiimides, and polysilacarbosilazanes.

24. The method according to claim 22 wherein a dual damascene structure is fabricated that comprises at least one via that is connected to the at least two interconnect lines.

25. A method for fabricating a damascene or dual damascene interconnect structure which comprise forming a damascene or dual damascene interconnect structure with at least two interconnect lines and wherein the at least two interconnect lines are embedded in a first dielectric; and depositing a dielectric hard mask in the space between said interconnect lines and nominally coplanar with the top surface of said lines, and said hard mask being deposited by a supercritical fluid based process or an atomic layer deposition from a tertiary amine based reagent and/or silylating agent.

26. The method according to claim 25 wherein the barrier cap dielectric is selected from the group consisting of poly-silanes and silynes, poly-oxycarbosilanes, poly-silazanes, poly-oxycarboxilazanes, polycarbosilanes, polysiloxazanes, polycarbosilazanes, polysilylcarbodiimides, and polysilacarbosilazanes.

27. The method according to claim 25 wherein a dual damascene structure is fabricated that comprises at least one via that is connected to the at least two interconnect lines.

28. A method for fabricating a damascene or dual damascene interconnect structure which comprises forming a damascene or dual damascene interconnect structure with a least two interconnect lines and wherein the at least two interconnect lines are embedded in a first dielectric; and optionally dielectric hard mask spanning the space between said interconnect lines and nominally coplanar with the top surface of said lines and a diffusion barrier cap dielectric on top of the at least two interconnect lines; which comprises:
depositing a first dielectric and optionally the dielectric hard mask using supercritical fluid based processing;
patterning photoresist layers to form the at least two interconnect line pattern on top;
transferring the at least two interconnect line pattern into the dielectric using photolithography and reactive ion etching;
stripping the residual photoresist using plasma ashing;
repairing any plasma damage to the first dielectric and the optional hard mask using a supercritical fluid based silylation treatment;
filling the interconnect lines and vias with a conductive liner and a conductive fill material;
planarizing the conductive liner and conductive fill material using chemical mechanical polishing;
cleaning the top of said at least two interconnect lines and said optional dielectric hard mask using supercritical fluid based cleaning solutions;
repairing any incidental damage to the first and/or second dielectric surface by silylation;
and depositing a diffusion barrier cap dielectric using a supercritical fluid based deposition.

29. The method according to claim 28 wherein the first dielectric is selected from the group consisting of porous and nonporous versions of organosilicates and combinations thereof.

30. The method according to claim 28 wherein the optional hard mask is selected from the group consisting of polysilanes, polysilynes, polyoxycarbosilanes, polysilazanes, polyoxycarbosilazanes, polycarbosilanes, polysilasilazanes, polysilacarbosilanes, polysiloxazanes, polycarbosilazanes, polysilylcarbodiimides, polysilacarbosilazanes, polyalkenylsilanes, polyalkylsilanes, polyalkynylsilanes, polyarylsilanes, and polysilsesquiazanes.

31. The method according to claim 28 wherein the conductive liner is selected from the group consisting of W, Ta, and Ti, nitrides thereof, siliconitrides thereof and combinations thereof.

32. The method according to claim 28 wherein the conductive filler material is selected from the group consisting of Cu, Al, Au, Ag and combinations and alloys thereof.

33. The method according to claim 28 wherein the cleaning utilizes mild etchants dissolved in supercritical fluids to clean the surface of the conductive fill material prior to the deposition of the diffusion barrier cap dielectric.

34. The method according to claim 28 wherein the diffusion barrier cap dielectric is selected from the group consisting of poly-silanes and silylenes, poly-oxycarbosilanes, poly-silazanes, poly-oxycarbosilazanes, polycarbosilanes, polysilasilazanes, polysilacarbosilanes, polysiloxazanes, polycarbosilazanes, polysilylcarbodiimides, and polysilacarbosilazanes.

35. The method according to claim 28 wherein the silylation for repairing any incidental damage to the first and/or second dielectric surface is a liquid phase, vapor phase or super critical CO₂ phase and the silylating agent is selected from the group consisting of alkoxysilanes, aminosilanes, chlorosilanes, silazanes and mixtures thereof.
